(19) United States
(12) Patent Application Publication
(10) Pub. No.: US 2019/0341362 A1
(43) Pub. Date: Nov. 7, 2019

(54) SEMICONDUCTOR DEVICE

(71) Applicant: TOYOTA JIDOSHA KABUSHIKI KAISHA, Toyota-shi (JP)

(72) Inventors: Takanori KAWASHIMA, Anjo-shi (JP); Makoto IMAI, Toyota-shi (JP)

(73) Assignee: TOYOTA JIDOSHA KABUSHIKI KAISHA, Toyota-shi, Aichi (JP)

(21) Appl. No.: 16/364,581

(22) Filed: Mar. 26, 2019

(30) Foreign Application Priority Data
May 7, 2018 (JP) 2018-089084

(51) Int. Cl. H01L 23/62; H01L 23/488; H01L 23/31; H01L 25/11; H03K 17/081; H01H 85/02; H01H 85/10

(52) U.S. Cl. CPC H01L 23/62; H01L 23/488; H01L 23/3107; H01L 25/115; B60L 58/00; H03K 17/08116; H01H 85/0241; H01H 85/10; H01H 2085/0283; H03K 17/08104

(57) ABSTRACT

A semiconductor device may include a semiconductor module, a busbar, and a connection member. The semiconductor module may include a semiconductor element and a power terminal connected to the semiconductor element. The power terminal of the semiconductor module may be connected to the busbar via the connection member. A fusing current of the connection member may be smaller than each of fusing currents of the power terminal and the busbar.

### CROSS-REFERENCE

This application claims priority to Japanese Patent Application No. 2018089084, filed on May 7, 2018, the entire contents of which are incorporated herein by reference.

### TECHNICAL FIELD

The technique disclosed herein relates to a semiconductor device including a semiconductor module.

### BACKGROUND

Japanese Patent Application Publication No, 2013-401993 describes a semiconductor module. The semiconductor module has a switching structure that is opened when an overcurrent flows therethrough.

### SUMMARY

As in the above-mentioned semiconductor module, when an overcurrent flows through a semiconductor module, it is desirable to quickly cut off the overcurrent. However, providing a switching structure in the semiconductor module complicates a structure of the semiconductor module and adversely affects electrical characteristics of the semiconductor module, for example, increasing its impedance. In this regard, the disclosure herein provides a new technique that can cut off an overcurrent flowing through a semiconductor module.

A semiconductor device disclosed herein may comprise: a semiconductor module comprising a semiconductor element and a power terminal connected to the semiconductor element; and a busbar connected to the power terminal of the semiconductor module via a connection member. A fusing current of the connection member is smaller than each of fusing currents of the power terminal and the busbar. That is, when the same overcurrent flows through the power terminal, the connection member, and the busbar, the connection member is fused before the power terminal and the busbar are fused.

With the above-mentioned configuration, when an overcurrent flows through the semiconductor module, the connection member is fused, and the overcurrent is thereby quickly cut off. Since the connection member is provided outside the semiconductor module, a structure of the semiconductor module does not need to be changed, and thus electrical characteristics of the semiconductor module are not changed either. A part of the busbar or power terminal may be replaced with the connection member, as compared to a structure in which the busbar and the power terminal are directly joined together, and as such, a size of the semiconductor device is not significantly enlarged. The fusing current of the connection member can be adjusted depending on a structure and material of the connection member and can be determined according to an allowable maximum current (i.e., rated current) of the semiconductor module.

### BRIEF DESCRIPTION OF DRAWINGS

FIG. 1 is a front view schematically showing a structure of a semiconductor device 2.

FIG. 2 is a plan view schematically showing the structure of the semiconductor device 2.

FIG. 3 is a cross-sectional view of the semiconductor device taken along a line III-III in FIG. 1.

FIG. 4 is a circuit diagram showing an electrical structure of the semiconductor device 2.

FIG. 5 shows a side view of a first connection member 40.

FIG. 6 shows a plan view of the first connection member 40.

FIG. 7 is a cross-sectional view of the semiconductor device taken along a line VII-VII in FIG. 6.

### DETAILED DESCRIPTION

In one embodiment of the present technique, a joint interface between a connection member and a power terminal may be parallel with a joint interface between the connection member and a busbar. With such a configuration, the connection member can be joined to both the power terminal and the busbar from a same direction.

In the above-mentioned embodiment, the joint interface between the connection member and the power terminal may be located in a same plane where the joint interface between the connection member and the busbar is located. With such a configuration, a joining process for the connection member and the power terminal and a joining process for the connection member and the busbar are easily performed simultaneously or sequentially.

In another embodiment of the present technique, a semiconductor module may further include an encapsulant encapsulating a semiconductor element. In this case, the power terminal may include a first portion extending outside from the encapsulant and a second portion extending along a direction perpendicular to a direction along which the first portion extends. The connection member may be joined to the second portion of the power terminal. With such a configuration, for example, even when a plurality of semiconductor modules is stacked, the connection members can be easily joined to the power terminals of the semiconductor modules,

In another embodiment of the present technique, a material of the connection member may have a melting point which is lower than each of melting points of materials of the power terminal and the busbar. In another embodiment, the material of the connection member may be same as the material of the power terminal or the busbar. In this case, a fusing current of the connection member can be adjusted not only by the material of the connection member, but also by a structure (for example, a size of a cross-sectional area) of the connection member.

In another embodiment of the present technique, the connection member may include an inner portion and an outer portion covering the inner portion. In this case, a material of the inner portion may have electric resistivity which is lower than electric resistivity of a material of the outer portion. With such a configuration, when an overcurrent flows through the connection member, an amount of heat generated in the inner portion increases, by which the connection member can be surely fused.

In another embodiment of the present technique, the connection member may include a bent portion at an intermediate position in a longitudinal direction of the connection member. With such a configuration, for example, when the semiconductor module vibrates, its vibrations can be absorbed in the bent portion. Thus, an excessive force can be avoided from acting on the joint interface between the connection member and the power terminal and on the joint interface between the connection member and the busbar.

In another embodiment of the present technique, the connection member may include a weak portion where a cross section of the connection member that is oriented perpendicular to the longitudinal direction thereof is locally reduced. With such a configuration, when an overcurrent flows through the connection member, the connection member can be surely fused in the weak portion.

In another embodiment of the present technique, a semiconductor device may include a first semiconductor module, a second semiconductor module, a first busbar, a second busbar, and a third busbar. In this case, the first semiconductor module may include a first switching element, a first power terminal, and a second power terminal. The first power terminal may be connected to the second power terminal via the first switching element. The second semiconductor module may include a second switching element, a third power terminal, and a fourth power terminal. The third power terminal may be connected to the fourth power terminal via the second switching element. The first busbar may be connected to the first power terminal of the first semiconductor module via the first connection member. The second busbar may be connected to the second power terminal of the first semiconductor module via a second connection member and may be connected to the third power terminal of the second semiconductor module via a third connection member. The third busbar may be connected to the fourth power terminal of the second semiconductor module via a fourth connection member. A fusing current of the first connection member may be smaller than each of fusing currents of the first power terminal and the first busbar. A fusing current of the second connection member may be smaller than each of fusing currents of the second power terminal and the second busbar. A fusing current of the third connection member may be smaller than each of fusing currents of the third power terminal and the second busbar. A fusing current of the fourth connection member may be smaller than each of fusing currents of the fourth power terminal and the third busbar. With such a configuration, when an overcurrent flows through at least one of the first semiconductor module and the second semiconductor module, any one of the first to fourth connection members is fused to thereby quickly cut off the overcurrent.

Representative, non-limiting examples of the present invention will now be described in further detail with reference to the attached drawings. This detailed description is merely intended to teach a person of skill in the art further details for practicing preferred aspects of the present teachings and is not intended to limit the scope of the invention. Furthermore, each of the additional features and teachings disclosed below may be utilized separately or in conjunction with other features and teachings to provide improved semiconductor devices, as well as methods for using and manufacturing the same.

Moreover, combinations of features and steps disclosed in the following detailed description may not be necessary to practice the invention in the broadest sense, and are instead taught merely to particularly describe representative examples of the invention. Furthermore, various features of the above-described and below-described representative examples, as well as the various independent and dependent claims, may be combined in ways that are not specifically and explicitly enumerated in order to provide additional useful embodiments of the present teachings.

All features disclosed in the description and/or the claims are intended to be disclosed separately and independently from each other for the purpose of original written disclosure, as well as for the purpose of restricting the claimed subject matter, independent of the compositions of the features in the embodiments and/or the claims. In addition, all value ranges or indications of groups of entities are intended to disclose every possible intermediate value or intermediate entity for the purpose of original written disclosure, as well as for the purpose of restricting the claimed subject matter.

A semiconductor device 2 according to an embodiment will be described with reference to the accompanied drawings. The semiconductor device 2 is employed in, for example, a power controller of an electric vehicle, and can constitute at least a part of a power conversion circuit, such as a converter or an inverter. The term electric vehicle as used herein broadly means vehicles having motors for driving wheels, and examples of the electric vehicle includes an electric vehicle charged by an external electric power, a hybrid vehicle having an engine in addition to a motor, a fuel cell vehicle powered by a fuel cell, and the like.

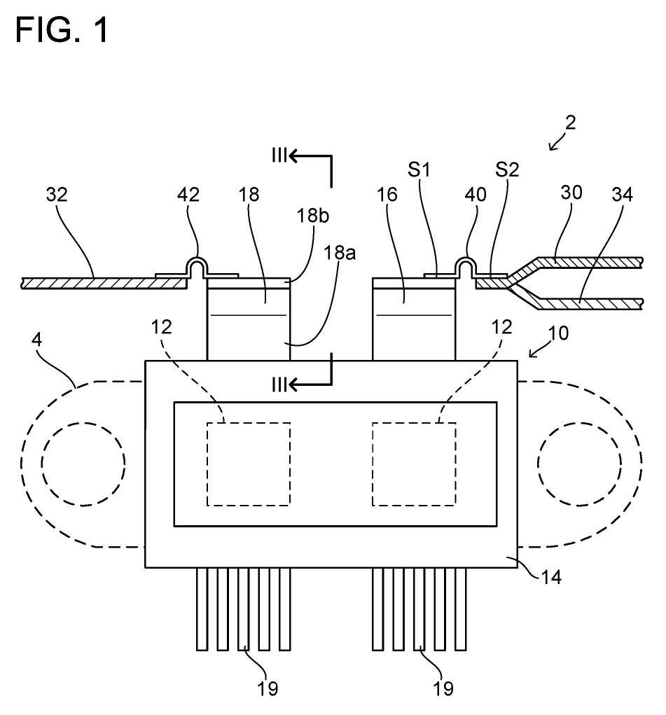

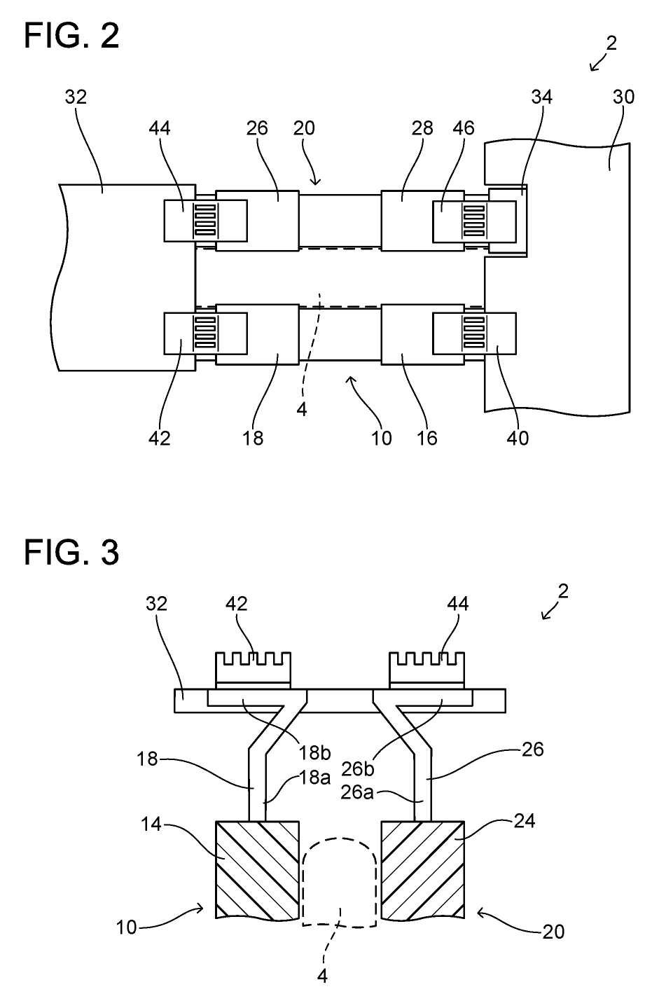

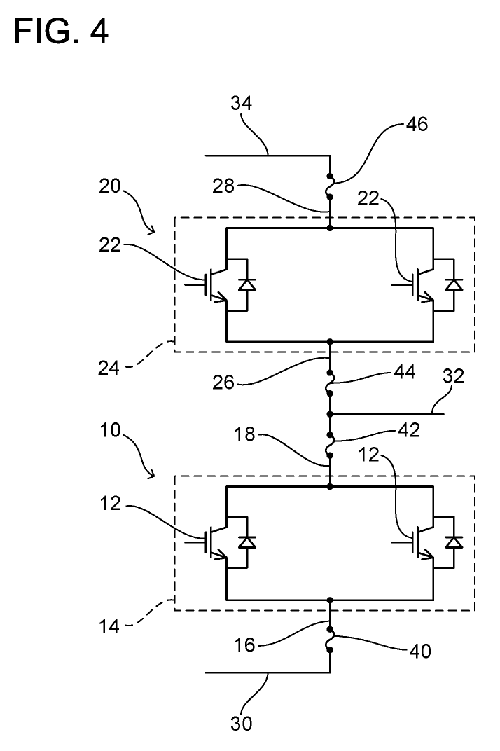

As shown in FIGS. 1 to 4, the semiconductor device 2 includes a first semiconductor module 10 and a second semiconductor module 20. The second semiconductor module 20 is stacked with respect to the first semiconductor module 10. A cooler 4 may be disposed between the first semiconductor module 10 and the second semiconductor module 20. The semiconductor device 2 may further include semiconductor modules in a greater number, in addition to the first semiconductor module 10 and the second semiconductor module 20. In this case, the semiconductor device 2 may have a structure including combinations of the first semiconductor module 10 and the second semiconductor module 20 described herein with the cooler 4 interposed therebetween being arranged repeatedly.

The first semiconductor module 10 includes a plurality of first semiconductor elements 12, a first encapsulant 14 encapsulating the plurality of first semiconductor elements 12, a first power terminal 16 and a second power terminal 18 that protrude from the first encapsulant 14, and a plurality of signal terminals 19. The first power terminal 16 and the second power terminal 18 are connected to the plurality of first semiconductor elements 12 inside the first encapsulant 14. The first semiconductor elements 12 are connected in parallel with each other between the first power terminal 16 and the second power terminal 18.

The first semiconductor elements 12 are so-called power semiconductor elements for a power circuit and have a same configuration with each other. The first semiconductor element 12 in the present embodiment is not particularly limited, but includes a switching element, such as a Metal-Oxide-Semiconductor Field-Effect Transistor (MOSFET) or a Reverse Conducting-Insulated Gate Bipolar Transistor (IGBT). One end (e.g., a source or emitter) of the first semiconductor element 12 is connected to the first power terminal 16, While the other end (e.g., a drain or collector) of the first semiconductor element 12 is connected to the second power terminal 18. The first semiconductor element 12 may further include a diode, in addition to the switching element. In this case, an anode of the diode is connected to the first power terminal 16, while a cathode of the diode is connected to the second power terminal 18.

The first encapsulant 14 is not particularly limited, but may be constituted of a thermosetting resin, such as an epoxy resin, or any other insulator. The first encapsulant 14 is also referred to as, for example, a molding resin or a package. In the present embodiment, the first encapsulant 14 has a substantially plate shape, and the plurality of first semiconductor elements 12 is arranged along a direction parallel to the plate shape of the first encapsulant 14. It is noted that a number of the first semiconductor elements 12 is not particularly limited. The first semiconductor module 10 may include at least one first semiconductor element 12.

Each of the first power terminal 16 and the second power terminal 18 is constituted of a conductor, such as copper or aluminum. The first power terminal 16 and the second power terminal 18 extend from inside to outside of the first encapsulant 14. The first power terminal 16 and the second power terminal 18 protrude from the first encapsulant 14 in the same direction. The first power terminal 16 and the second power terminal 18 are not particularly limited, but have a same shape. As shown in FIG. 3, the second power terminal 18 is a plate-shaped member that is bent and includes a first portion 18a protruding from the first encapsulant 14 and a second portion 18b extending in a direction (left-right direction in FIG. 3) perpendicular to the direction (up-down direction in FIG. 3) in which the first portion 18a extends. The first power terminal 16 also has the first portion and second portion which are similar to those of the second power terminal 18.

The second semiconductor module 20 includes a plurality of second semiconductor elements 22, a second encapsulant 24 encapsulating the plurality of second semiconductor elements 22, a third power terminal 26 and a fourth power terminal 28 that protrude from the second encapsulant 24, and a plurality of signal terminals (not shown), The third power terminal 26 and the fourth power terminal 28 are connected to the plurality of second semiconductor elements 22 inside the second encapsulant 24. The second semiconductor elements 22 are connected in parallel with each other between the third power terminal 26 and the fourth power terminal 28.

The second semiconductor elements 22 are so-called power semiconductor elements for a power circuit and have a same configuration with each other. Each second semiconductor element 22 in the present embodiment is not particularly limited, but includes a switching element, such as a MOSFET or an IGBT. One end (e.g., a source or emitter) of the second semiconductor element 22 is connected to the third power terminal 26, while the other end (e.g., a drain or collector) of the second semiconductor element 22 is connected to the fourth power terminal 28. The second semiconductor element 22 may further include a diode, in addition to the switching element. In this case, an anode of the diode is connected to the third power terminal 26, while a cathode of the diode is connected to the fourth power terminal 28.

The second encapsulant 24 is not particularly limited, but can be constituted of a thermosetting resin, such as an epoxy resin, or any other insulator. The second encapsulant 24 is also referred to as, for example, a molding resin or a package. In the present embodiment, the second encapsulant 24 has a substantially plate shape, and the second semiconductor elements 22 are arranged along a direction parallel to the plate shape of the second encapsulant 24. It is noted that a number of the second semiconductor elements 22 is not particularly limited. The second semiconductor module 20 may include at least one second semiconductor element 22.

Each of the third power terminal 26 and the fourth power terminal 28 is constituted of a conductor, such as copper or aluminum. The third power terminal 26 and the fourth power terminal 28 extend from inside to outside of the second encapsulant 24. The third power terminal 26 and the fourth power terminal 28 protrude from the second encapsulant 24 in a same direction. The third power terminal 26 and the fourth power terminal 28 are not particularly limited, but have a same shape with each other. As shown in FIG. 3, the third power terminal 26 is a plate-shaped member that is bent and includes a first portion 26a protruding from the second encapsulant 24 and a second portion 26b extending in a direction (left-right direction in FIG. 3) perpendicular to the direction (up-down direction in FIG. 3) in which the first portion 26a extends. The fourth power terminal 28 also has the first portion and second portion which are similar to those of the third power terminal 26.

In the semiconductor device 2 of the present embodiment, the first semiconductor module 10 and the second semiconductor module 20 have a same structure, and are arranged in postures by which they are inverted upside down from each other. In another embodiment, the first semiconductor module 10 and the second semiconductor module 20 may have different structures from each other. Furthermore, a number of the semiconductor modules 10 and 20 is not particularly limited. The semiconductor device 2 may include at least one semiconductor module.

The semiconductor device 2 further includes a first busbar 30, a second busbar 32, and a third busbar 34. The first busbar 30 is connected to the first power terminal 16 of the first semiconductor module 10 via the first connection member 40. The second busbar 32 is connected to the second power terminal 18 of the first semiconductor module 10 via a second connection member 42. The second busbar 32 is also connected to the third power terminal 26 of the second semiconductor module 20 via a third connection member 44. Furthermore, the third busbar 34 is connected to the fourth power terminal 28 of the second semiconductor module 20 via a fourth connection member 46.

With the above-mentioned connection configuration, the first semiconductor module 10 and the second semiconductor module 20 are connected in series between the first busbar 30 and the third busbar 34. Furthermore, the second busbar 32 is connected between the first semiconductor module 10 and the second semiconductor module 20. Such a circuit configuration can constitute a pair of upper and lower arms in the power conversion circuit, such as a converter or an inverter.

The first connection member 40 is constituted of a conductor, for example, metal, and electrically connects the first power terminal 16 and the first busbar 30, A fusing current of the first connection member 40 is smaller than each of fusing currents of the first power terminal 16 and the first busbar 30. Therefore, the first connection member 40 can function as a fuse between the first power terminal 16 and the first busbar 30. Similarly, the second connection member 42 is constituted of a conductor, for example, metal, and electrically connects the second power terminal 18 and the second busbar 32. A fusing current of the second connection member 42 is smaller than each of fusing currents of the second power terminal 18 and the second busbar 32. Therefore, the second connection member 42 can function as a fuse between the second power terminal 18 and the second busbar 32. Thus, when an overcurrent flows through the first semiconductor module 10, the first connection member 40 or second connection member 42 is fused, and the overcurrent is thereby quickly cut off.

Here, in order to configure the fusing current of the first connection member 40 smaller than each of the fusing currents of the first power terminal 16 and the first busbar 30, a cross section of the first connection member 40 may be set smaller than each of cross sections of the first power terminal 16 and the first busbar 30, Additionally or alternatively, a material of the first connection member 40 may have a melting point which is lower than each of melting points of materials of the first power terminal 16 and the first busbar 30. Similarly, in order to configure the fusing current of the second connection member 42 smaller than each of the fusing currents of the second power terminal 18 and the second busbar 32, a cross section of the second connection member 42 may be set smaller than each of cross sections of the second power terminal 18 and the second busbar 32. Additionally or alternatively, a material of the second connection member 42 may have a melting point which is lower than each of melting points of materials of the second power terminal 18 and the second busbar 32.

The third connection member 44 is constituted of a conductor, for example, metal, and electrically connects the third power terminal 26 and the second busbar 32. A fusing current of the third connection member 44 is smaller than each of fusing currents of the third power terminal 26 and the second busbar 32. Therefore, the third connection member 44 can function as a fuse between the third power terminal 26 and the second busbar 32. Similarly, the fourth connection member 46 is constituted of a conductor, for example, metal, and electrically connects the fourth power terminal 28 and the third busbar 34. A fusing current of the fourth connection member 46 is smaller than each of fusing currents of the fourth power terminal 28 and the third busbar 34. Therefore, the fourth connection member 46 can function as a fuse between the fourth power terminal 28 and the third busbar 34. Thus, when an overcurrent flows through the second semiconductor module 20, the third connection member 44 or fourth connection member 46 is fused, and the overcurrent is thereby quickly cut off.

Here, in order to make the fusing current of the third connection member 44 smaller than each of the fusing currents of the third power terminal 26 and the second busbar 32, a cross section of the third connection member 44 may be set smaller than each of cross sections of the third power terminal 26 and the second busbar 32. Additionally or alternatively, a material of the third connection member 44 may have a melting point which is lower than each of melting points of materials of the third power terminal 26 and the second busbar 32. Similarly, in order to make the fusing current of the fourth connection member 46 smaller than each of the fusing currents of the fourth power terminal 28 and the third busbar 34, a cross section of the fourth connection member 46 may be set smaller than each of cross sections of the fourth power terminal 28 and the third busbar 34. Additionally or alternatively, a material of the fourth connection member 46 may have a melting point which is lower than each of melting points of materials of the fourth power terminal 28 and the third busbar 34.

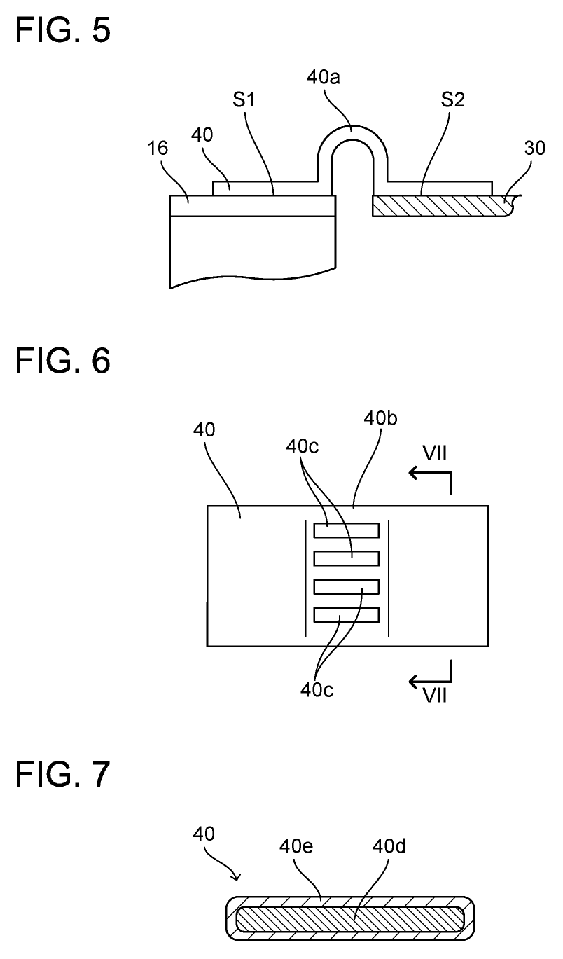

As shown in FIGS. 1 and 5, a joint interface S1 between the first connection member 40 and the first power terminal 16 is parallel with a joint interface 82 between the first connection member 40 and the first busbar 30. With such a configuration, the first connection member 40 can be joined to both the first power terminal 16 and the first busbar 30 which are parallel with each other, from a same direction. Additionally, in the semiconductor device 2 of the present embodiment, the joint interface S1 between the first connection member 40 and the first power terminal 16 is located in a same plane where the joint interface S2 between the first connection member 40 and the first busbar 30 is located. With such a configuration, a joining process for the first connection member 40 and the first power terminal 16 and a joining process for the first connection member 40 and the first busbar 30 are easily performed simultaneously or sequentially. Such a configuration is also employed in the other connection members 42, 44, and 46.

As shown in FIGS. 1 and 3, the second connection member 42 is joined to the second portion 18b of the second power terminal 18. The second portion 18b is parallel with a direction in Which the two semiconductor modules 10 and 20 are stacked (in the left-right direction of FIG. 3) and also parallel with the second busbar 32. With such a configuration, even when the two semiconductor modules 10 and 20 are stacked, an excessive force can be avoided from acting on the second power terminal 18 of the first semiconductor module 10. The first connection member 40 in the present embodiment has a U-shaped bent portion 40a, but a shape of the bent portion 40a is not particularly limited. The other connection members 42, 44, and 46 also employ a same structure as the bent portion 40a.

As shown in FIG. 6, the first connection member 40 includes a weak portion 40b at an intermediate position in a longitudinal direction of the first connection member 40. A plurality of slots 40c is formed in the weak portion 40b, and thus a cross section of the first connection member 40 perpendicular to its longitudinal direction is locally reduced in the weak portion 40b. With such a configuration, a current density in the weak portion 40b increases when an overcurrent flows through the first connection member 40, by which the first connection member 40 can be surely fused in the weak portion 40b. Here, the weak portion 40b may be provided with one or more notches, in addition to or instead of hole(s), such as the slots 40c. Alternatively, a dimension, including width, thickness, diameter, etc. of the first connection member 40 may be locally reduced in the weak portion 40b. The other connection members 42, 44, and 46 also employ a same structure as the weak portion 40b.

As shown in FIG. 7, the first connection member 40 includes an inner portion 40d and an outer portion 40e covering the inner portion 40d. The inner portion 40d and the outer portion 40e are constituted of different materials. The material of the inner portion 40d has electric resistivity which is lower than electric resistivity of the material of the outer portion 40e. With such a configuration, when an overcurrent flows through the first connection member 40, an amount of heat generated in the inner portion 40d is larger than an amount of heat generated in the outer portion 40e. The heat generated in the inner portion 40d is hardly dissipated to outside and thereby quickly increases a temperature of the first connection member 40. Thus, when an overcurrent flows through the first connection member 40, the first connection member 40 is fused in a short time, and the overcurrent is thereby quickly cut off Such a multilayer structure is also employed in the other connection members 42, 44, and 46.

What is claimed is:

1. A semiconductor device comprising:
a semiconductor module comprising a semiconductor element and a power terminal connected to the semiconductor element; and
a busbar connected to the power terminal of the semiconductor module via a connection member,
wherein
a fusing current of the connection member is smaller than each of fusing currents of the power terminal and the busbar.

2. The semiconductor device according to claim 1, wherein a joint interface between the connection member and the power terminal is parallel with a joint interface between the connection member and the busbar.

3. The semiconductor device according to claim 2, wherein the joint interface between the connection member and the power terminal is located in a same plane Where a joint interface between the connection member and the busbar is located.

4. The semiconductor device according to claim 2, wherein
the semiconductor module further comprises an encapsulant encapsulating the semiconductor element,
the power terminal comprises a first portion extending outside from the encapsulant and a second portion extending along a direction perpendicular to a direction along which the first portion extends, and
the connection member is joined at the second portion of the power terminal.

5. The semiconductor device according to claim 1, wherein a material of the connection member has a melting point which is lower than each of melting points of materials of the power terminal and the busbar.

6. The semiconductor device according to claim 1, wherein
the connection member comprises an inner portion and an outer portion covering the inner portion, and
a material of the inner portion has electric resistivity which is lower than electric resistivity of a material of the outer portion.

7. The semiconductor device according to claim 1, wherein the connection member comprises a bent portion at an intermediate position in a longitudinal direction of the connection member.

8. The semiconductor device according to claim 1, wherein the connection member comprises a weak portion where a cross section of the connection member is locally reduced, the cross section being perpendicular to a longitudinal direction of the connection member.

9. A semiconductor device comprising:
a first semiconductor module comprising a first switching element, a first power terminal, and a second power terminal, the first power terminal connected to the second power terminal via the first switching element;
a second semiconductor module comprising a second switching element, a third power terminal, and a fourth power terminal, the third power terminal connected to the fourth power terminal via the second switching element;
a first busbar connected to the first power terminal of the first semiconductor module via a first connection member;
a second busbar connected to the second power terminal of the first semiconductor module via a second connection member and connected to the third power terminal of the second semiconductor module via a third connection member; and
a third busbar connected to the fourth power terminal of the second semiconductor module via a fourth connection member,
wherein
a fusing current of the first connection member is smaller than each of fusing currents of the first power terminal and the first busbar,
a fusing current of the second connection member is smaller than each of fusing currents of the second power terminal and the second busbar,
a fusing current of the third connection member is smaller than each of fusing currents of the third power terminal and the second busbar, and
a fusing current of the fourth connection member is smaller than each of fusing currents of the fourth power terminal and the third busbar.
